(19) United States
(12) Patent Application Publication
(10) Pub. No.: US 2025/0210607 A1
(43) Pub. Date: Jun. 26, 2025

(54) HETEROJUNCTION BIPOLAR TRANSISTOR WAFERS WITH BACKSIDE SUB-COLLECTOR CONTACT

(71) Applicant: GlobalFoundries U.S. Inc., Malta, NY (US)

(72) Inventors: Vibhor Jain, Clifton Park, NY (US); Anupam Dutta, Krishnapur (IN); John J. Pekarik, Underhill, VT (US); Alexander M. Derrickson, Saratoga Springs, NY (US); Oscar D. Restrepo, Halfmoon, NY (US); Vvss Satyasuresh Choppalli, Bangalore (IN)

(21) Appl. No.: 18/392,464

(22) Filed: Dec. 21, 2023

(51) Int. Cl. H01L 25/18; H01L 25/00; H01L 25/07

(52) U.S. Cl. CPC H01L 25/18; H01L 25/074; H01L 25/50

(57) ABSTRACT

The present disclosure relates to semiconductor structures and, more particularly, to heterojunction bipolar transistor wafers with backside sub-collector contact and methods of manufacture. The structure includes: a first chiplet comprising a first device with a backside contact; and a second chiplet connected to the first chiplet, the second chiplet comprising a second device with a frontside contact.

### BACKGROUND

The present disclosure relates to semiconductor structures and, more particularly, to heterojunction bipolar transistor wafers with a backside sub-collector contact and methods of manufacture.

A heterojunction bipolar transistor (HBT) is a type of bipolar junction transistor (BJT) which uses differing semiconductor materials for the emitter and base regions or collector and base regions, creating a heterojunction. The HBT can handle signals of very high frequencies, up to several hundred GHz. The HBT is commonly used in ultrafast circuits, mostly radio frequency (RF) systems, and in applications requiring a high power efficiency, such as RF power amplifiers in cellular phones due to good RF performance, high breakdown voltage and integration with CMOS devices. SiGe HBT devices have a higher power dissipation and combining them into a 3D process results in degradation of performance due to excessive self-heating.

### SUMMARY

In an aspect of the disclosure, a structure comprises: a first chiplet comprising a first device with a backside contact; and a second chiplet connected to the first chiplet, the second chiplet comprising a second device with a frontside contact.

In an aspect of the disclosure, a structure comprises: a first chiplet comprising a heterojunction bipolar transistor, the heterojunction bipolar transistor comprising a sub-collector, a collector, a base and an emitter; a backside contact directly contacting to the sub-collector; and a second chiplet connected to the first chiplet, the second chiplet comprising a CMOS device with a frontside contact connecting to the heterojunction bipolar transistor.

In an aspect of the disclosure, a method comprises: forming a first chiplet comprising a first device with a backside contact; and forming a second chiplet connected to the first chiplet, the second chiplet comprising a second device with a frontside contact.

### BRIEF DESCRIPTION OF THE DRAWINGS

The present disclosure is described in the detailed description which follows, in reference to the noted plurality of drawings by way of non-limiting examples of exemplary embodiments of the present disclosure.

FIG. 1 shows a structure and respective fabrication processes in accordance with aspects of the present disclosure.

FIG. 2 shows a structure and respective fabrication processes in accordance with additional aspects of the present disclosure.

FIG. 3 shows a structure and respective fabrication processes in accordance with further aspects of the present disclosure.

FIGS. 4A-4D show process steps for fabricating the structure of FIG. 3 in accordance with aspects of the present disclosure.

### DETAILED DESCRIPTION

The present disclosure relates to semiconductor structures and, more particularly, to heterojunction bipolar transistor wafers with a backside sub-collector contact and methods of manufacture. In embodiments, the heterojunction bipolar transistor wafers with the backside sub-collector contact can be bonded to a CMOS wafer. Advantageously, the heterojunction bipolar transistor wafers with the backside sub-collector contact provide reduced self-heating, lower Ccb (collector to base capacitance) and lower Rc (collector resistance), in addition to a reduced chip area. In addition, the heterojunction bipolar transistor wafers provide a simplified process of manufacture, e.g., reduces masking steps.

In more specific embodiments, an HBT chiplet (wafer) may be bonded to a CMOS chiplet. A sub-collector of the HBT chiplet directly connects to a backside metal using a bottom contact through, for example, an insulator layer, e.g., buried oxide, and passivation layer. In embodiments, a width of each of the emitter, collector and sub-collector is less than the width of the base region, e.g., intrinsic base and extrinsic base. An interconnect may be coupled to the emitter and/or base with the interconnect coupled to a backside metal.

The structures of the present disclosure can be manufactured in a number of ways using a number of different tools. In general, though, the methodologies and tools are used to form structures with dimensions in the micrometer and nanometer scale. The methodologies, i.e., technologies, employed to manufacture the structures of the present disclosure have been adopted from integrated circuit (IC) technology. For example, the structures are built on wafers and are realized in films of material patterned by photolithographic processes on the top of a wafer. In particular, the fabrication of the structures uses three basic building blocks: (i) deposition of thin films of material on a substrate, (ii) applying a patterned mask on top of the films by photolithographic imaging, and (iii) etching the films selectively to the mask. In addition, precleaning processes may be used to clean etched surfaces of any contaminants, as is known in the art. Moreover, when necessary, rapid thermal anneal processes may be used to drive-in dopants or material layers as is known in the art.

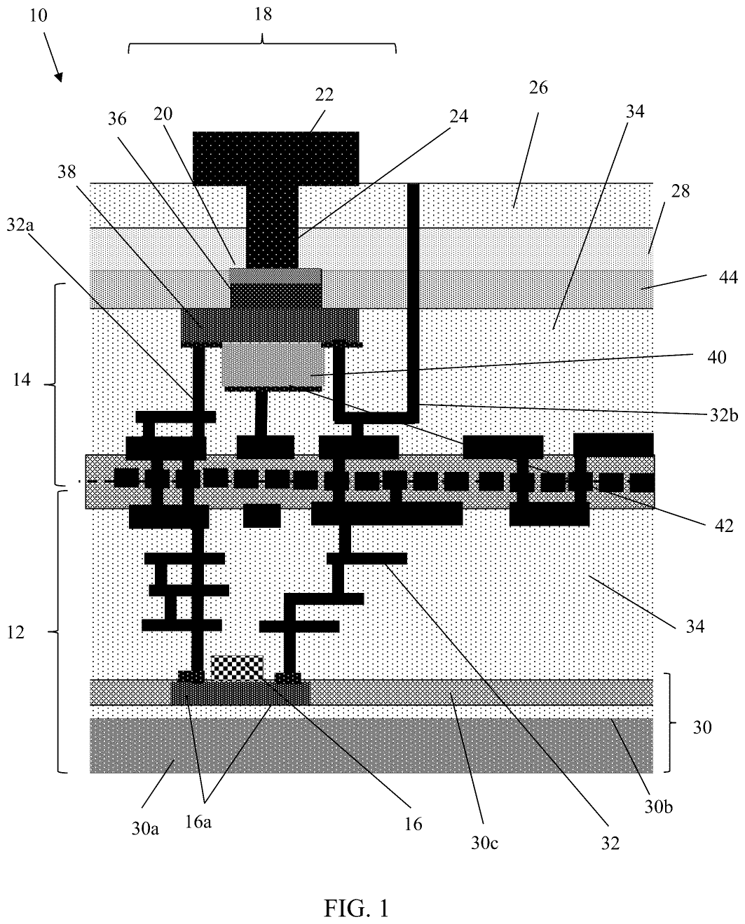

FIG. 1 shows a structure and respective fabrication processes in accordance with aspects of the present disclosure. More specifically, the structure 10 comprises a bottom wafer (e.g., chiplet) 12 bonded to a top wafer (e.g., chiplet) 14. In embodiments, the bottom wafer 12 comprises a CMOS device or other set of devices as represented at reference numeral 16 and the top wafer 14 comprises an HBT 18. The HBT 18, for example, includes a sub-collector 20 directly connected to backside metal 22 using a bottom contact 24 passing through a passivation layer 26 and, in embodiments, an insulator layer 28, e.g., buried oxide material.

More specifically, the bottom wafer (e.g., chiplet) 12 comprises a transistor 16 formed on semiconductor on insulator (SOI) substrate 30, as an example. In embodiments, SOI substrate 30, from bottom to top, may include a handle substrate 30a, a buried insulator layer 30b, and a top semiconductor layer 30c. The handle substrate 30a and top semiconductor layer 30c may include a semiconductor material such as, for example, Si, Ge, SiGe, SiC, SiGeC, a III-V compound semiconductor, a II-VI compound semiconductor or any combinations thereof. The top semiconductor layer 30c may comprise any suitable single crystallographic orientation (e.g., a (100), (110), (111), or (001) crystallographic orientation). The buried insulator layer 30b may include silicon dioxide, silicon nitride, silicon oxynitride, boron nitride or a combination thereof. In embodiments, the buried insulator layer 30b may be a buried oxide (BOX). In embodiments, the bottom wafer 30 may be a bulk silicon.

Still referring to FIG. 1, the transistor 16 may include a gate dielectric material gate electrode, and sidewall spacers as is known in the art. In embodiments, it should be recognized that the use of a transistor 16 in the CMOS wafer 12 is provided as an illustrative, non-limiting example, and that other CMOS devices are also contemplated herein. For example, the CMOS device may be any active or passive device such as an inductor, capacitor, etc.

As an exemplary explanation of the transistor 16, the gate dielectric material of the transistor 16 may be a low-k or high-k dielectric material e.g., HfO₂ Al₂O₃, Ta₂O₃, TiO₂, La₂O₃, SrTiO₃, LaALO₃, ZrO₂, Y₂O₃, Gd₂O₃, and combinations thereof. The gate electrode may be, for example, polysilicon material. The sidewall spacers may be an oxide material, nitride material, or combinations thereof. The transistor 16 may also include source and drain regions 16a as is known in the art such that no further explanation is required for a complete understanding of the present disclosure. The transistor 16 including, e.g., source and drain regions 16a, may connect to wiring structures 32 embedded within interlevel dielectric material 34 as is known in the art.

FIG. 1 further shows the top wafer (e.g., chiplet) 14 bonded to the bottom wafer (e.g., chiplet) 12. In embodiments, the top wafer 14 may be an HBT wafer bonded to the bottom wafer 12 by interlevel dielectric material 34, e.g., oxide material. The bonding may be, for example, by conventional thermal oxide bonding processes, e.g., wafer bonding, and/or other suitable methods. In embodiments, the wiring structures 32 may connect to the wiring structures 32a of the top wafer 12 as discussed in more detail herein.

In embodiments, the top wafer may include an HBT 18 comprising the sub-collector 20, a collector 36, a base 38 and an emitter 40. In embodiments, the sub-collector 20 and the collector 36 may be semiconductor material, e.g., Si material and, preferably, N+ doped Si material. The sub-collector 20 may directly connect to a backside metal 22 using a bottom contact 24 passing through the passivation layer 26 and, in embodiments, an insulator layer 28, e.g., buried oxide material. In embodiments, the passivation layer 26 may be nitride material or oxide material. The bottom contact 24 may be, for example, an interconnect structure comprising, for example, tungsten aluminum, TiN, TaN, etc. The base 38, e.g., extrinsic and intrinsic base, may be Si or SiGe material and the emitter 40 may be polysilicon or single crystal silicon material. The backside metal 22 may connect to an I/O port.

In embodiments, the sub-collector 20 and the collector 36 may be formed by an epitaxial growth process. In more specific embodiments, the sub-collector 20 and the collector 36 may be formed by an epitaxial growth process with an in-situ doping. In embodiments, the in-situ doping would use an N+ dopant. In embodiments, the N+ dopant may be, e.g., Arsenic (As), Phosphorus (P) or Antimony (Sb), among other suitable examples. The base 38 may also be formed by an epitaxial growth process using, e.g., Si or SiGe.

The interconnect structure 24 can be formed by conventional lithography, etching and deposition methods known to those of skill in the art. For example, a resist formed over the passivation layer 26 is exposed to energy (light) and developed utilizing a conventional resist developer to form a pattern (opening). An etching process with a selective chemistry, e.g., reactive ion etching (RIE), will be used to transfer the pattern from the patterned photoresist layer to form one or more trenches in the passivation layer 26 and insulator layer 28, exposing the backside of the sub-collector 20. Following the resist removal by a conventional oxygen ashing process or other known stripants, conductive material can be deposited by any conventional deposition processes, e.g., chemical vapor deposition (CVD) processes. Any residual material on the surface of the passivation layer 26 can be removed by conventional chemical mechanical polishing (CMP) processes.

In further embodiments, the emitter 40 and the base 38 may be connected to the CMOS wafer 12 and, preferably, the transistor 16 through the use of the wiring structures 32, 32a. As an example, the wiring structures 32, 32a may be 3D heterogeneously integrated (3DHI) contact structures. The base 38 may also be connected to backside wiring by wiring structures 32b, passing through the passivation layer 26 and the insulator layer 28. The wiring structures 32b may be formed using conventional lithography, etching and deposition processes as described herein. In further embodiments, the width of the emitter 40, collector 36 and sub-collector 20 is less than the width of the base 38, e.g., intrinsic base and extrinsic base. The collector 36 and sub-collector 20 may be surrounded by insulator material 44, e.g., buried oxide material or sidewall spacers; whereas the base 38 and emitter 40 are provided in the interlevel dielectric material 34.

The emitter 40 and the base 38 (and transistor 16 of the CMOS wafer 12) may include silicide contacts 42 connecting to the wiring structures 32, 32a, 32b. As should be understood by those of skill in the art, the silicide process begins with deposition of a thin transition metal layer, e.g., nickel, cobalt or titanium, over fully formed and patterned semiconductor material (e.g., transistor 16, source and drain regions 16a, base 38 and emitter 40). After deposition of the material, the structure is heated allowing the transition metal to react with exposed silicon (or other semiconductor material as described herein) forming a low-resistance transition metal silicide. Following the reaction, any remaining transition metal is removed by chemical etching, leaving silicide contacts 42 in the active regions of the device.

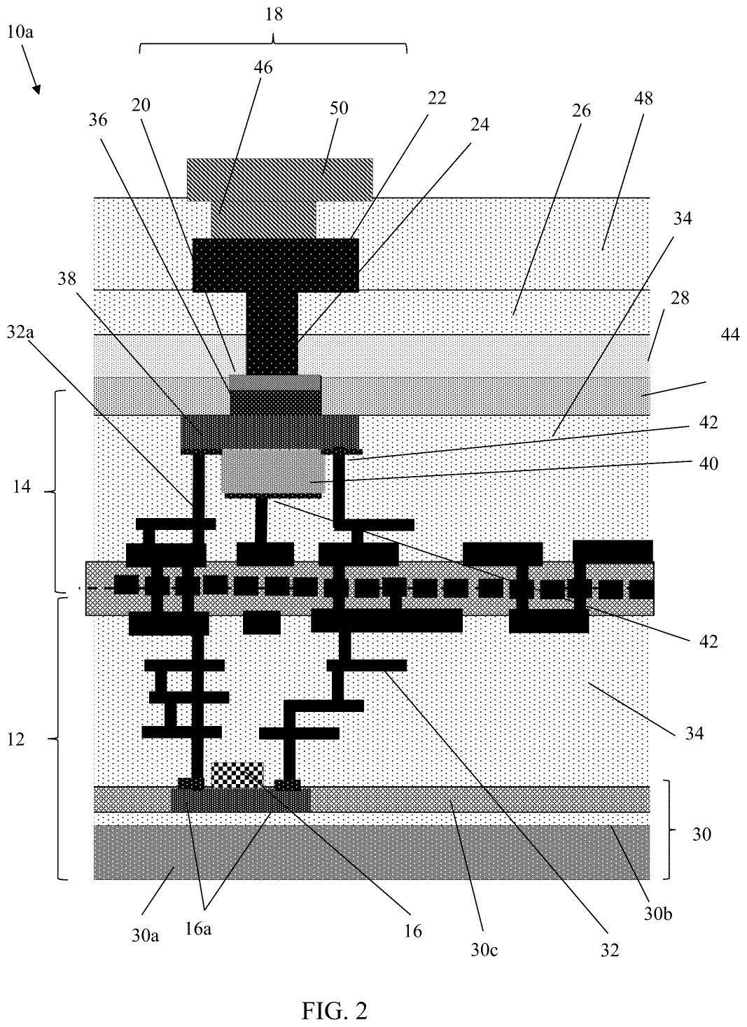

FIG. 2 shows a structure and respective fabrication processes in accordance with additional aspects of the present disclosure. In the structure 10a of FIG. 2, the backside metal 22 connects, e.g., directly contacts, to a redistribution layer 46 embedded within dielectric material 48. In embodiments, the dielectric material 48 may be an oxide or other interlevel dielectric material. The redistribution layer 46 may connect to a final metal layer 50, e.g., back side connection. As should be understood by those of skill in the art, the redistribution layer 46 is an extra metal layer on an integrated circuit that makes its I/O pads available in other locations of the chip, for increased access to the pads where necessary. The remaining features of the structure 10a are similar to the structure 10 shown in FIG. 1.

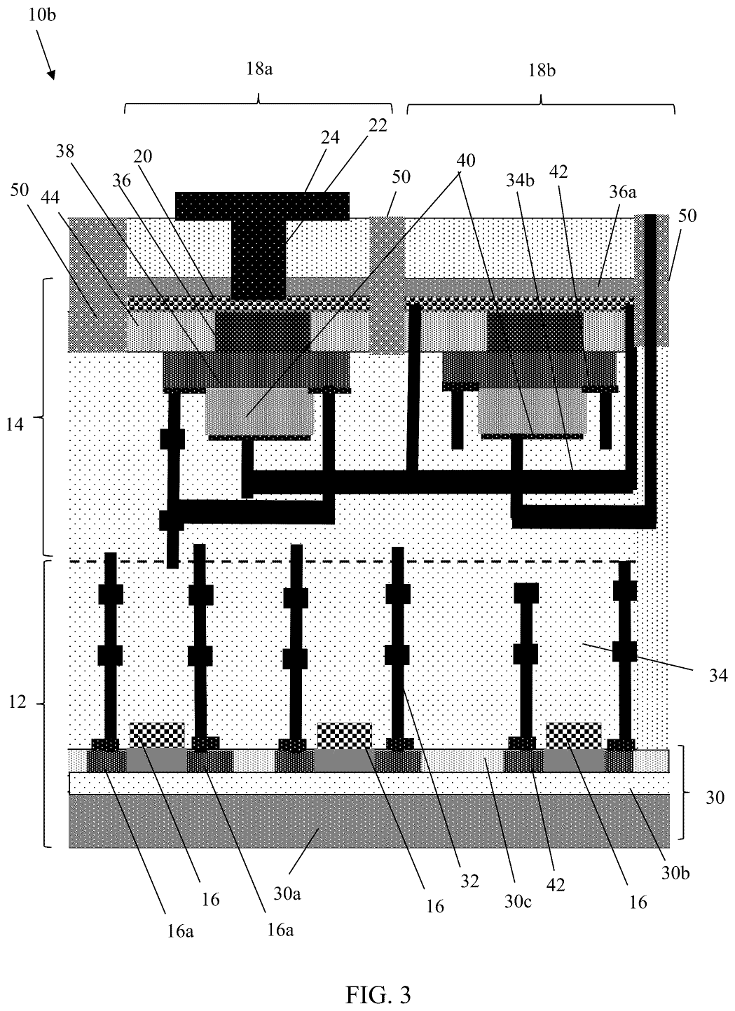

FIG. 3 shows a structure and respective fabrication processes in accordance with additional aspects of the present disclosure. In the structure 10b of FIG. 3, the bottom wafer 12 may include multiple transistors 16 and the top wafer 14 may be one or multiple wafers bonded together, which include multiple HBT structures 18a, 18b connected in series. The multiple HBT structures 18a, 18b may be used as a cascode power amplifier.

In this embodiment, the sub-collector 20 and collector 36 of the HBT structure 18a may be connected to the backside metal 24 by the interconnect 22; whereas the sub-collector 20 and collector 36 of the HBT structure 18b may be connected to the emitter 40 of the HBT structure 18a using frontside wiring structures 34c. In addition, the emitter 40 of the HBT structure 18a may be connected to the sub-collector 20 and collector 36 of the HBT structure 18b; whereas the emitter 40 may be connected to a backside (e.g., I/O port). The HBT structures 18a, 18b can be wired to form a cascode amplifier where structure 18a forms a common base device and 18b forms a common emitter device.

In addition, in this structure 10b, the sub-collector 20 may be formed by a blanket ion implantation process with an n+ dopant in a bulk semiconductor substrate 36a. In addition, the collector 36 may be formed by an epitaxial growth process with an in-situ doping, with isolation regions 44 surrounding the collector 36. Moreover, deep trench isolation structures 50 may be used as a polish stop. The deep trench isolation structures 50 may be filled with high density oxide, as an example.

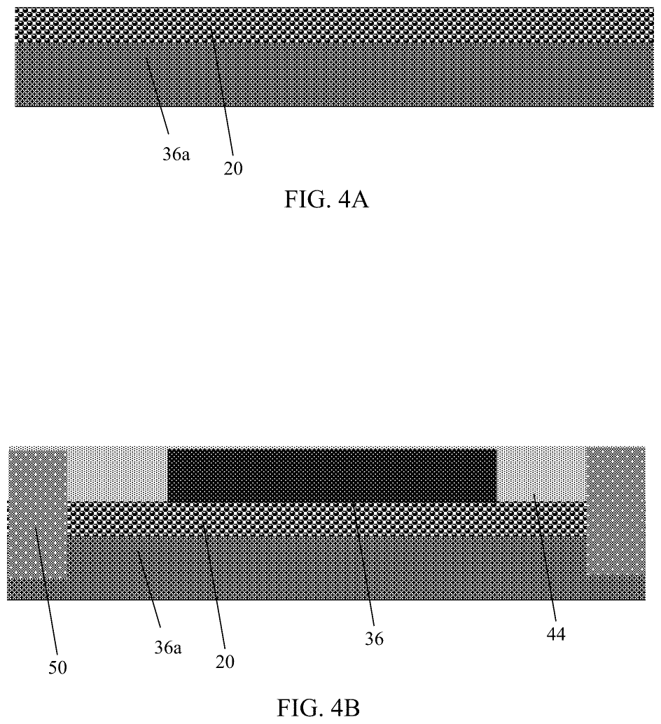

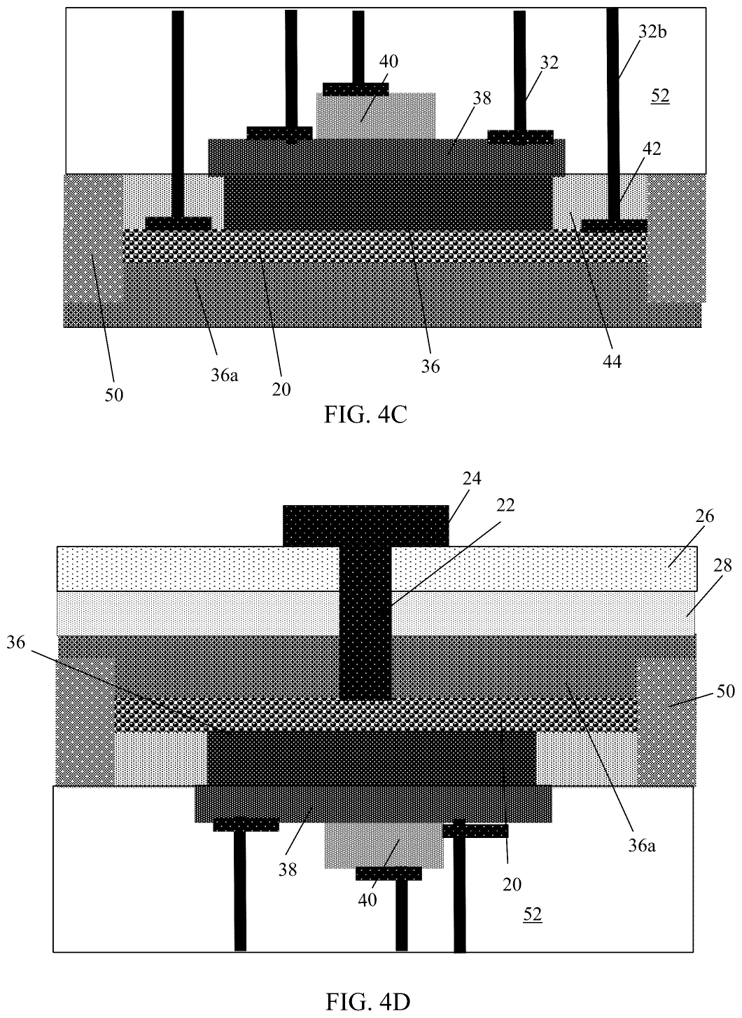

FIGS. 4A-4D show process steps for fabricating the structure of FIG. 3 in accordance with further aspects of the present disclosure. It should be recognized that similar process steps may be used for fabricating the structures of FIGS. 2 and 3. For example, the structures of FIGS. 2 and 3 will use an epitaxial growth process for the collector and sub-collector, and not have a blanket implant process to form the collector region.

In FIG. 4A, the fabrication processes begin with a blanket ion implantation process to form the sub-collector 20. In embodiments, the blanket ion implantation process may be performed on a bulk semiconductor substrate 36a. The bulk semiconductor substrate 36a may be, for example, Si material. In the structures of FIGS. 1 and 2, the sub-collector 20 may be formed by an epitaxial growth process with an in-situ doping as is known in the art.

The blanket ion implantation process may include introducing a dopant in the bulk substrate 36a. In embodiments, respective patterned implantation masks may be used to define selected areas exposed for the implantations. The implantation mask used to select the exposed area for forming sub-collector 20 is stripped after implantation. The implantation masks may include a layer of a light-sensitive material, such as an organic photoresist, applied by a spin coating process, pre-baked, exposed to light projected through a photomask, baked after exposure, and developed with a chemical developer. Each of the implantation masks has a thickness and stopping power sufficient to block masked areas against receiving a dose of the implanted ions. The collector 36 is doped with p n-type dopants, e.g., Arsenic (As), Phosphorus (P) and Antimony (Sb), among other suitable examples.

In FIG. 4B, the collector 36 may be formed over the sub-collector 20. In embodiments, the collector 36 may be formed an epitaxial growth process with an in-situ doping. The in-situ doping may be an n-type dopant. In embodiments, the collector 36 may be SiP. An insulator material (e.g., spacers) 44 may be deposited over the sub-collector 20, and patterned using conventional lithography and etching processes (e.g., anisotropic etching processes) as is known in the art and described herein.

Still referring to FIG. 4B, deep trench isolation structures 50 may be formed extending into the semiconductor substrate 36a. The deep trench isolation structures 50 can be formed by conventional lithography, etching and deposition methods known to those of skill in the art. For example, a resist formed over the insulator material 44 is exposed to energy (light) and developed utilizing a conventional resist developer to form a pattern (opening). An etching process with a selective chemistry, e.g., reactive ion etching (RIE), will be used to transfer the pattern to form one or more trenches extending into the semiconductor substrate 36a. Following the resist removal by a conventional oxygen ashing process or other known stripants, high density oxide can be deposited by any conventional deposition processes, e.g., chemical vapor deposition (CVD) processes. Any residual material on the surface of the insulator material 44 can be removed by conventional chemical mechanical polishing (CMP) processes.

In FIG. 4C, the base 38 and emitter 40 are formed over the collector 36 and sub-collector 20. The base 38 and emitter 40 may be formed by conventional epitaxial growth processes. In embodiments, the base 38 can be an intrinsic base and a raised extrinsic base. The base 38 may be SiGe material, for example. The emitter 40 may be N+ polysilicon material. In embodiments, the emitter 40 may be heavily doped with N+ dopants. In optional embodiments, the base 38 may be doped with p-type dopants. In embodiments, the base layer 38 may include a raised extrinsic base region outside the emitter (not shown).

Still referring to FIG. 4C, the wiring structures 32 may be formed through interlevel dielectric material 52, contacting to the base 38, emitter 40 and the sub-collector 20. In this device, the collector includes a front-side contact 32b. The wiring structures 32 may be formed by conventional lithography, etching and deposition processes as already described herein. Prior to the formation of the wiring structures 32, silicide contacts 42 may be formed. The silicide contacts 42 may be formed as described with respect to the structure of FIG. 1.

In FIG. 4D, another HBT device can be formed on another chiplet in the fabrication processes as described, with the exception that the front-side contact 32b is eliminated. In this structure, the chiplet can be flipped over and the backside metal 22 and bottom contact 24 can be formed, passing through a passivation layer 26 and, in embodiments, an insulator layer 28, e.g., buried oxide material. Prior to the formation of the backside metal 22 and bottom contact 24, the passivation layer 26 and insulator layer 28 may be formed by any conventional deposition method, e.g., chemical vapor deposition (CMP) processes. Following the deposition process, the backside metal 22 and bottom contact 24 can be formed by conventional lithography and etching processes as described herein.

Referring back to FIG. 3, for example, the completed wafers can be bonded together. In the case of FIG. 3, for example, different wafers comprising the HBT structures 18a, 18b can be bonded together at the deep trench isolation structures 50. In preferred embodiments, the bonding may be performed prior to the formation of the backside metal 22 and bottom contact 24. In this way, the wiring structures can be formed to connect the HBT structures 18a, 18b as described herein and as is known in the art such that no further explanation is required for a complete understanding of the present disclosure. The CMOS wafer 12 can be bonded to the wafers 14 and connections made to the HBT structures 18a, 18b as is known in the art.

The structures can be utilized in system on chip (SoC) technology. The SoC is an integrated circuit (also known as a “chip”) that integrates all components of an electronic system on a single chip or substrate. As the components are integrated on a single substrate, SoCs consume much less power and take up much less area than multi-chip designs with equivalent functionality. Because of this, SoCs are becoming the dominant force in the mobile computing (such as in Smartphones) and edge computing markets. SoC is also used in embedded systems and the Internet of Things.

The method(s) as described above is used in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed:

1. A structure comprising:
a first chiplet comprising a first device with a backside contact; and
a second chiplet connected to the first chiplet, the second chiplet comprising a second device with a frontside contact.

2. The structure of claim 1, wherein the first device comprises a heterojunction bipolar transistor and the second device comprises a CMOS transistor electrically connecting to the heterojunction bipolar transistor.

3. The structure of claim 1, wherein the first device comprises a heterojunction bipolar transistor comprising a sub-collector, a collector, a base and an emitter, and the backside contact contacts to the sub-collector.

4. The structure of claim 3, wherein a width of the base is greater than a width of the emitter, a width of the collector and a width of the sub-collector.

5. The structure of claim 3, further comprising a third device connecting to the first device, the third device and the first device comprising a cascode power amplifier.

6. The structure of claim 5, further comprising deep trench isolation structures isolating the first device from the third device.

7. The structure of claim 5, wherein the third device comprises a heterojunction bipolar transistor with a front side connection to a sub-collector.

8. The structure of claim 1, wherein the backside contact extends through an insulator material and passivation layer.

9. The structure of claim 1, wherein the backside contact connects between a sub-collector of the first device and a redistribution layer.

10. The structure of claim 1, wherein the first device connects to the second device by wiring structures extending through interlevel dielectric material through the frontside contact.

11. The structure of claim 10, wherein the wiring structures comprise 3D heterogeneously integrated (3DHI) contact structures.

12. The structure of claim 3, wherein the collector comprises a blanket implantation in a bulk semiconductor substrate.

13. A structure comprising:
a first chiplet comprising a heterojunction bipolar transistor, the heterojunction bipolar transistor comprising a sub-collector, a collector, a base and an emitter;
a backside contact contacting to the sub-collector; and
a second chiplet connected to the first chiplet, the second chiplet comprising a CMOS device with a frontside contact connecting to the heterojunction bipolar transistor.

14. The structure of claim 13, wherein the CMOS device comprises a transistor electrically connecting to the heterojunction bipolar transistor.

15. The structure of claim 13, wherein a width of the base is greater than a width of the emitter, a width of the collector and a width of the sub-collector.

16. The structure of claim 13, further comprising a third device connecting to the first device, the third device and the first device comprising a cascode power amplifier with the third device comprising a emitter contact through a backside.

17. The structure of claim 16, further comprising deep trench isolation structures isolating the first device from the third device.

18. The structure of claim 13, wherein the backside contact extends through an insulator material and passivation layer on a backside of the first chiplet.

19. The structure of claim 13, wherein the backside contact connects between a sub-collector of the first device and a redistribution layer.

20. A method comprising:
forming a first chiplet comprising a first device with a backside contact; and
forming a second chiplet connected to the first chiplet, the second chiplet comprising a second device with a frontside contact.
